(19) United States
(12) Patent Application Publication
(10) Pub. No.: US 2015/0078061 A1
(43) Pub. Date: Mar. 19, 2015

(54) SEMICONDUCTOR MEMORY DEVICE AND SEMICONDUCTOR DEVICE MOUNTING THE SEMICONDUCTOR MEMORY DEVICE

(71) Applicant: PANASONIC CORPORATION, Osaka (JP)

(72) Inventors: Masanori SHIRAHAMA, Shiga (JP); Toshiaki KAWASAKI, Osaka (JP); Kazuhiro TAKEMURA, Shiga (JP); Yasuhiro AGATA, Osaka (JP)

(21) Appl. No.: 14/550,551

(22) Filed: Nov. 21, 2014

Related U.S. Application Data
(63) Continuation of application No. PCT/JP2013/003071, filed on May 14, 2013.

(30) Foreign Application Priority Data
May 29, 2012 (JP) 2012-121900

(51) Int. Cl. G11C 17/08

(52) U.S. Cl. CPC G11C 17/08
USPC 365/103

(57) ABSTRACT

A semiconductor memory device includes a non-volatile device array of once rewritable non-volatile devices arranged in a matrix. The device includes a plurality of non-volatile device sub-arrays formed by dividing the non-volatile device array; a power interconnect contact region provided between at least one of pairs of the plurality of non-volatile device sub-arrays, and connected to a power interconnect provided at an upper layer of the non-volatile device array; and an ESD protection circuit located in the power interconnect contact region between ground and a power source for the non-volatile devices.

### CROSS-REFERENCE TO RELATED APPLICATIONS

This is a continuation of International Application No. PCT/JP2013/003071 filed on May 14, 2013, which claims priority to Japanese Patent Application No. 2012-121900 filed on May 29, 2012. The entire disclosures of these applications are incorporated by reference herein.

### BACKGROUND

The present disclosure relates to semiconductor devices, and more particularly to semiconductor memory devices including electric fuses.

In recent years, various types of devices have higher function and performance. Information equipment have been required to have high security. For higher function and performance, manufacturing processes of most advanced semiconductor devices have been miniaturized. Particularly, in the field of the most advanced semiconductor devices such as system large scale integration (LSI), higher security has been demanded, and non-volatile devices of a relatively large number of bits tend to be buried inside the semiconductor devices.

On the other hand, in many cases, the manufacturing processes of semiconductor devices such as image sensors and analog LSI require less metal interconnect layers than the manufacturing processes of the most advanced semiconductor devices to improve the image quality and reduce costs. In particular, higher accuracy of the analog quantity is required in view of higher function. Memory defect relieving circuits, phase locked loop (PLL), analog quantity are tuned in memories, PLL circuits, analog circuits, etc., which are the elements mounted in the semiconductor devices.

Fuse elements (hereinafter referred to as electric fuses) are often used as simple program elements having the multilayer structure of a polysilicon layer and a silicide layer in each semiconductor device. As a known cutting method of the electric fuses, for example, as shown in Japanese Unexamined Patent Publication (Japanese Translation of PCT Application) No. H11-512879, a predetermined program potential is applied to the both ends to allow a current to flow through the silicide layer, thereby aggregating silicide to increase the resistance of the electric fuses.

As compared to the past, semiconductor devices using these electric fuses are demanded to have a large number of bits. With an increase in the number of bits, arrangement of electric fuses in a matrix (array) is employed in view of reducing an increase in the area of each semiconductor device. The semiconductor device also includes a protection circuit to protect the inner circuit from electro-static discharge (hereinafter referred to as ESD).

With a decrease in the number of interconnect layers available for the electric fuses arranged in the array, the number of metal interconnect layers connectable as power sources to the electric fuses decreases inside the semiconductor device. As a result, the resistance of the interconnects increases and a current is difficult to flow through the interconnects, thereby degrading the cutting quality of the electric fuses. In addition, with an increase in the resistance of the interconnects, the protection circuit may not effectively function.

As a solution to the problem, for example, Japanese Unexamined Patent Publication No. 2009-177044 suggests a semiconductor device including electric fuses. Specifically, the device includes, in addition to a single independent power source switching circuit, a plurality of fuse bit cells, each of which includes a fuse element connected to an output of the power source switching circuit at one end, and a first metal oxide semiconductor (MOS) transistor connected to the other end of the fuse element. The device further includes a diode connected between ground and the output of the power source switching circuit to address ESD.

### SUMMARY

On the other hand, in the circuit configuration particularly shown in FIGS. 7 and 8 of Japanese Unexamined Patent Publication No. 2009-177044, the diode for ESD protection and the power source switching circuit are collectively arranged outside an electric fuse section. This configuration increases the area of the electric fuse section when the capacity of the semiconductor device increases. This leads to insufficient power source to the inside the electric fuse section or insufficient ESD protection. These problems become significant when the power source for the electric fuses has higher resistance with a decrease in the number of interconnect layers.

In view of the problems, the present disclosure provides a semiconductor memory device including non-volatile devices such as electric fuses and reducing an increase in the circuit area even when the interconnect resistance increases, while improving the cutting quality of the electric fuses and the ESD protection.

To address the problem, the present disclosure provides the following solution. A semiconductor memory device including a non-volatile device array of once rewritable non-volatile devices arranged in a matrix. The device includes a plurality of non-volatile device sub-arrays formed by dividing the non-volatile device array; a power interconnect contact region provided between at least one of pairs of the plurality of non-volatile device sub-arrays, and connected to a power interconnect provided at an upper layer of the non-volatile device array; and an ESD protection circuit located in the power interconnect contact region between ground and a power source for the non-volatile devices.

With this configuration, even if the resistance of the interconnects is increased by a decrease in the number of interconnect layers of the semiconductor memory device, the distance of the interconnection between the power interconnect and each non-volatile device in the non-volatile device sub-arrays is shortened. This reduces an increase in the resistance of the interconnects. Thus, sufficient power source to, for example, electric fuses as the non-volatile devices is secured, thereby maintaining high cutting quality of the electric fuses. In addition to the reduction in the increase in the resistance of the interconnects, since the distances between the protected non-volatile devices and the ESD protection circuit are short, the function of the ESD protection circuit is exhibited to improve ESD protection. Furthermore, no exclusive region for the ESD protection circuit is needed by providing the ESD protection circuit in the power interconnect contact region, thereby reducing an increase in the area of the semiconductor memory device.

Alternatively, a semiconductor memory device including a non-volatile device array of once rewritable non-volatile devices arranged in a matrix. The device includes one or more column selection lines corresponding to columns of the non-volatile device array; and a plurality of write driver circuits separately provided on the column selection line such that the plurality of write driver circuits sandwich at least one of the non-volatile devices.

This configuration supplies sufficient power to the non-volatile devices sandwiched between the write driver circuits, thereby improving the cutting quality of, for example, electric fuses as the non-volatile devices.

The present disclosure reduces an increase in the area of the semiconductor memory device and differences in the cutting quality of the electric fuses, even if the area increases or the resistance of the interconnects themselves increases with an increase in the capacity of the memory cell array, or even if the power source supplying for, for example, the electric fuses as non-volatile devices has high resistance with a decrease in the number of the interconnect layers. Furthermore, the quality of the ESD protection is maintained and improved.

### BRIEF DESCRIPTION OF THE DRAWINGS

FIG. 1 is a schematic view illustrating the configuration of a semiconductor memory device according to a first embodiment.

FIG. 2 illustrates an example configuration of a cutting drive circuit of FIG. 1.

FIG. 3 is a schematic view illustrating the configuration of a semiconductor memory device according to a second embodiment.

FIG. 4 is a circuit diagram illustrating an example configuration of part of the plurality of memory cell sub-arrays and a cutting drive circuit of FIG. 3.

FIG. 5 is a schematic view illustrating the configuration of a semiconductor memory device according to a variation of the second embodiment.

FIG. 6 is a schematic view illustrating another example of the semiconductor memory device of FIG. 5.

FIG. 7 illustrates an example configuration of an ESD protection circuit according to the second embodiment.

FIG. 8 illustrates another example configuration of the ESD protection circuit according to the second embodiment.

FIG. 9 is a schematic view illustrating a semiconductor device according to a third embodiment.

FIG. 10 is a cross-sectional view of the semiconductor memory device taken along the line X-X of FIG. 5.

### DETAILED DESCRIPTION

A semiconductor memory device according to this embodiment will be described hereinafter with reference to the drawings. The same reference characters as those shown in the drawings are used to represent equivalent elements, and the explanation thereof will be omitted.

### First Embodiment

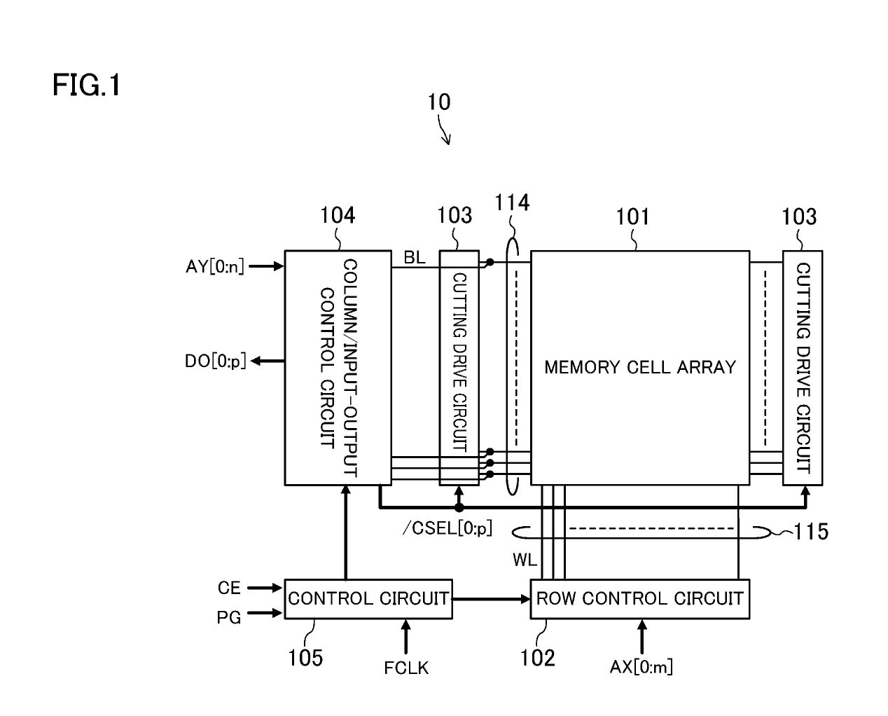

FIG. 1 is a schematic view illustrating the configuration of a semiconductor memory device according to a first embodiment.

A semiconductor memory device 10 shown in FIG. 1 includes a memory cell array 101 having an electric fuse array including electric fuses as non-volatile devices arranged in an array, a row control circuit 102 connected to the memory cell array 101, cutting drive circuits (write driver circuits) 103 connected to the memory cell array 101, a column/input-output control circuit 104 connected to the memory cell array 101 and the cutting drive circuits 103, and a control circuit 105 connected to the row control circuit 102 and the column/input-output control circuit 104. More specifically, the configuration is as follows.

The control circuit 105 receives a chip enable signal CE being a selection signal for selecting the memory cell array 101 and a program enable signal PG being a control signal as input signals, and a synchronization signal FCLK as a clock signal. The output signal of the control circuit 105 is input to the column/input-output control circuit 104 and the row control circuit 102. In this embodiment, the selection of the memory cell array 101 means the selection of the electric fuse array provided inside.

The row control circuit 102 receives an input address signal AX[0:m], where m is a positive integer, and decodes the address signal AX using the output signal of the control circuit 105 as a control signal to generate a row selection signal 115 for the memory cell array 101. The row selection signal 115 is sent to the memory cell array 101 via one of row selection lines WL, thereby selecting the electric fuse array inside the memory cell array 101.

The column/input-output control circuit 104 receives an input address signal AY[0:n], where n is a positive integer, and reads and writes data from and on memory cells included in the memory cell array 101. The column/input-output control circuit 104 generates a column selection signal 114 in reading data, and outputs the data, which has been output to a column selection line BL as a reading result of a memory cell (an electric fuse), as a data output signal DO[0:p], where p is a positive integer. On the other hand, the column/input-output control circuit 104 outputs a signal /CSEL[0:p] to the cutting drive circuits 103 in writing data.

When writing of the column/input-output control circuit 104 is enabled by the control of the control circuit 105, the cutting drive circuits 103 applies a potential required to cut the electric fuses to the column selection line BL of the memory cell array 101 based on the signal /CSEL[0:p].

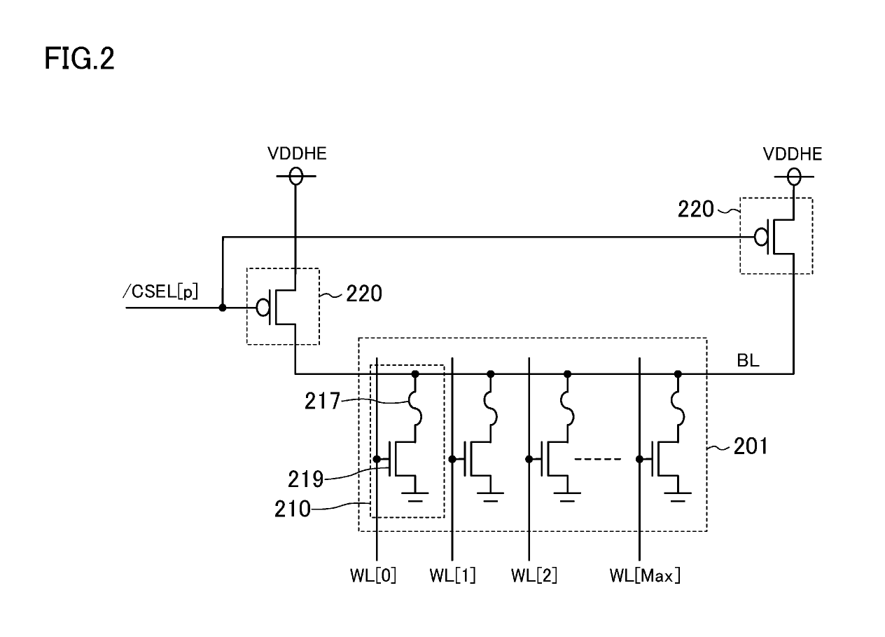

FIG. 2 is a circuit diagram illustrating an example configuration of part of the memory cell array and the cutting drive circuits of FIG. 1.

A memory cell array 201 includes a plurality of single memory cells 210. Each single memory cell 210 includes, for example, an electric fuse 217 made of the gate material of a transistor, and an n-type MIS transistor 219 receiving a row selection signal at a gate.

One end of the electric fuse 217 is connected to the column selection line BL. The memory cell array 101 of FIG. 1 is formed by arranging a plurality of the memory cell arrays 201 of FIG. 2 in an array. As a result, an electric fuse array is formed.

P-type MIS transistors 220, which are cutting drive circuits and also serve as driver circuits of the electric fuses 217, are provided at the both ends of the column selection line BL. Each of the p-type MIS transistors 220 is connected to VDDHE being a cutting power source of the electric fuses at a source, and connected to corresponding one end of the column selection line BL at a drain. An inverted column selection signal /CSEL[p] (signal /CSEL[p]), which has an inverted potential of the column selection signal CSEL[p], is input to gates of the p-type MIS transistors 220 in common The signal /CSEL[p] is generated by a peripheral circuit (e.g., the column/input-output control circuit 104 of FIG. 1) located at the end of the memory cell array 201, supplied via an upper interconnect of the memory cell array 201, and input to the p-type MIS transistors 220.

In FIG. 2, when the potential of each row selection line WL, which is the gate potential of the corresponding n-type MIS transistor 219, becomes high, and the signal /CSEL[p] becomes low, a cutting current is supplied from the both sides of the column selection line BL.

As described above, in the semiconductor memory device 10 according to this embodiment, the cutting drive circuits 103 are separately arranged to sandwich the memory cell array 101, thereby suppressing an increase in the area of the semiconductor memory device and improving the cutting quality of the electric fuses.

Specifically, using a large size transistor is conceivable to apply a voltage to one end of a column selection line to allow a current to flow to the other end. In this case, the area of the semiconductor memory device increases. In this case, since the electric fuses of the memory cells near the other end are distant from the power source, a sufficient current for cutting may not flow to the electric fuses. That is, the cutting quality may be different among the electric fuses.

By contrast, in this embodiment, a voltage can be applied from the both ends of the column selection line BL. Thus, a sufficient current flows through the column selection line BL even in using a small size transistor. This curbs an increase in the area of the semiconductor memory device 10, and makes the cutting quality of the electric fuses 217 uniform. As a result, the cutting quality of the electric fuses 217 improves.

In FIG. 2, the electric fuse array and the memory cell array 201 include a single row and a plurality of columns However, the array of this embodiment is not limited thereto, and may include one or more rows and a plurality of columns, or a plurality of rows and one or more columns

In the column selection line BL, the two cutting drive circuits 103 may not be arranged at the both ends of the memory cell array 201. For example, the two cutting drive circuits 103 may be arranged to sandwich at least one electric fuse.

A plurality of memory cell sub-arrays may be formed by dividing the memory cell array 201 in a matrix direction. In this case, for example, the cutting drive circuits 103 may be arranged to sandwich at least one of the memory cell sub-arrays. That is, the numbers of the memory cell sub-arrays and the cutting drive circuits 103 may be different.

### Second Embodiment

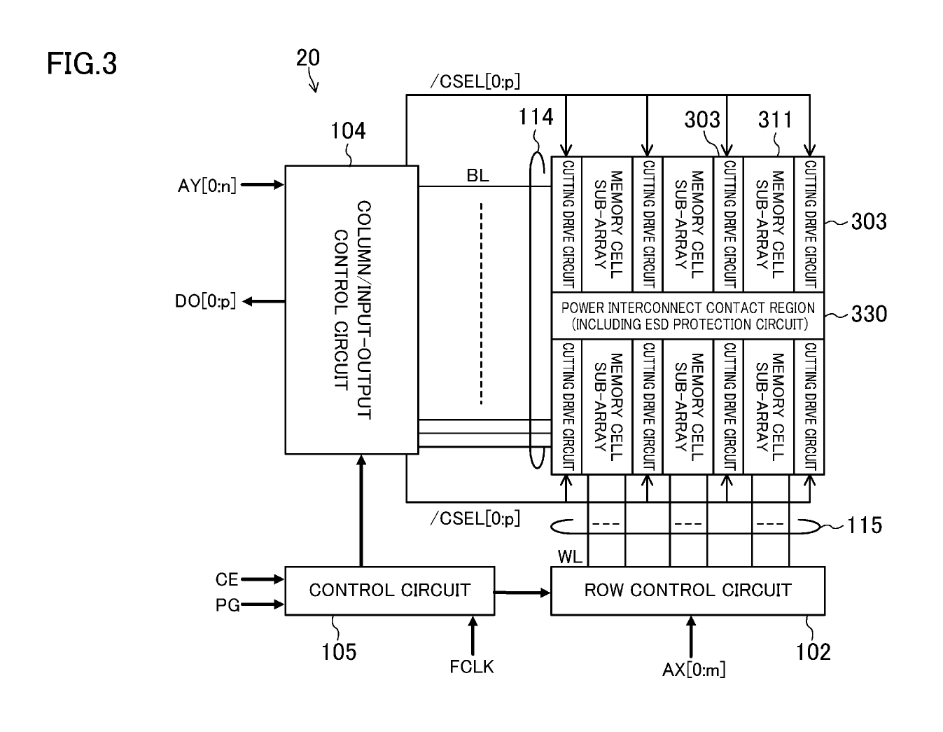

FIG. 3 is a schematic view illustrating the configuration of a semiconductor memory device according to a second embodiment.

The semiconductor memory device 10 of FIG. 1 includes a single block of the memory cell array 101, and the cutting drive circuits 103 arranged at the both ends of the memory cell array 101. On the other hand, a semiconductor memory device 20 shown in FIG. 3 includes a plurality of memory cell sub-arrays 311, three or more cutting drive circuits 303 corresponding to the memory cell sub-arrays 311, and a power interconnect contact region 330.

More specifically, the plurality of memory cell sub-arrays 311 are formed by dividing a memory cell array. The memory cell sub-arrays 311 and the cutting drive circuits 303 are alternately arranged. The cutting drive circuits 303 applies a cutting potential from the both sides of the column selection line BL of the memory cell sub-arrays 311 to cut the electric fuses in the corresponding memory cell sub-arrays 311.

As shown in FIG. 3, the power interconnect contact region 330 is surrounded by the plurality of memory cell sub-arrays 311 and the plurality of cutting drive circuits 303. The power interconnect contact region 330 is connected to a power interconnect provided at an upper layer of the memory cell sub-arrays 311. The power interconnect contact region 330 includes an ESD protection circuit, which is located between the power interconnect and the ground interconnect and connected to the memory cell sub-arrays 311 and the cutting drive circuits 303, directly under the power interconnect.

A specific example of the ESD protection circuit will be described later.

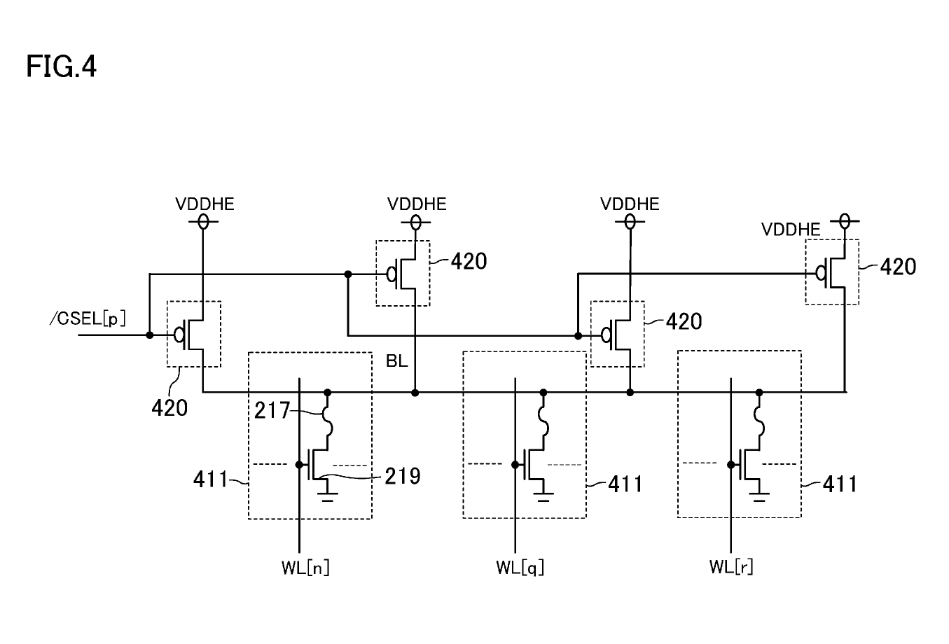

FIG. 4 is a circuit diagram illustrating an example configuration of part of the plurality of memory cell sub-arrays and the cutting drive circuits of FIG. 3.

Each of a plurality of memory cell sub-arrays 411 includes a plurality of single memory cells. Each single memory cell includes an electric fuse 217, and an n-type MIS transistor 219 receiving a row selection signal at a gate. One end of the electric fuse 217 is connected to a column selection line BL.

A plurality of p-type MIS transistors 420, which are cutting drive circuits and function as driver circuits of the electric fuses 217, are arranged to be connected to the both ends of the memory cell sub-arrays 411. Each p-type MIS transistor 420 is connected to the column selection line BL at a drain, and connected to VDDHE, which functions as a cutting power at a source. A signal /CSEL[p] are input to gates of the p-type MIS transistors 420 in common This signal /CSEL[p] is, for example, generated by a peripheral circuit (not shown) located outside the memory cell sub-arrays 411, supplied via upper interconnects of the plurality of memory cell sub-arrays 411, and input to the p-type MIS transistors 420.

As described above, in the semiconductor memory device 20 according to this embodiment, the plurality of the memory cell sub-arrays 311 formed by dividing the memory cell array are arranged, and the cutting drive circuits 303 are separately arranged to sandwich one of the memory cell sub-arrays 311. This shortens the distances between the memory cell sub-arrays 311 and the cutting drive circuits 303, thereby suppressing an increase in the area of the semiconductor memory device 20 and effectively reducing the differences in the cutting quality among the electric fuses.

The power and the ground potential are efficiently supplied from the power interconnect contact region 330 to the memory cell sub-arrays 311. Since the ESD protection circuit is located in the power interconnect contact region 330, an increase in the area of the semiconductor memory device 20 is prevented.

In the semiconductor memory device 20 of FIG. 3, the cutting drive circuits 303 are arranged at and connected to the both ends of all the memory cell sub-arrays 311. Alternatively, the semiconductor memory device 20 may include a memory cell sub-array either one end of which the cutting drive circuits 303 is arranged at and connected to. The cutting drive circuits 303 may be arranged on the column selection line BL to sandwich at least one of the plurality of memory cell sub-arrays 311.

### Variations

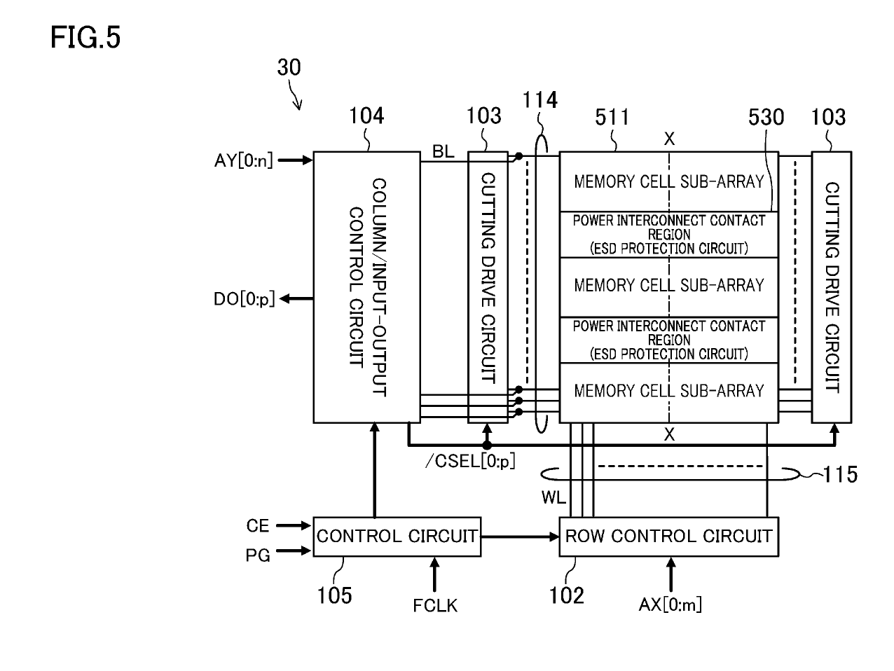

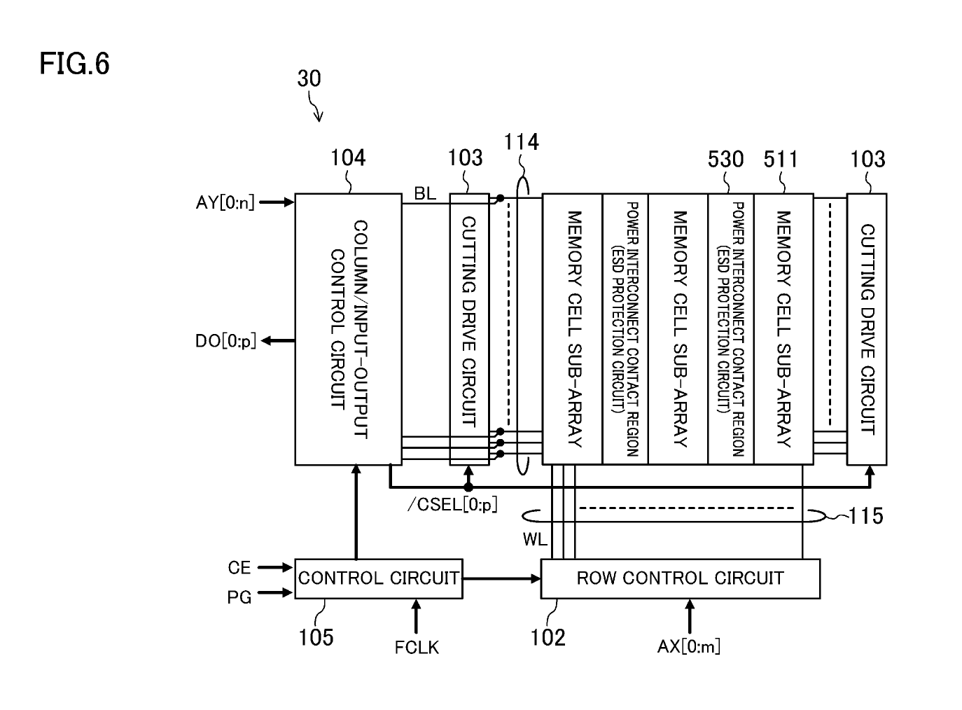

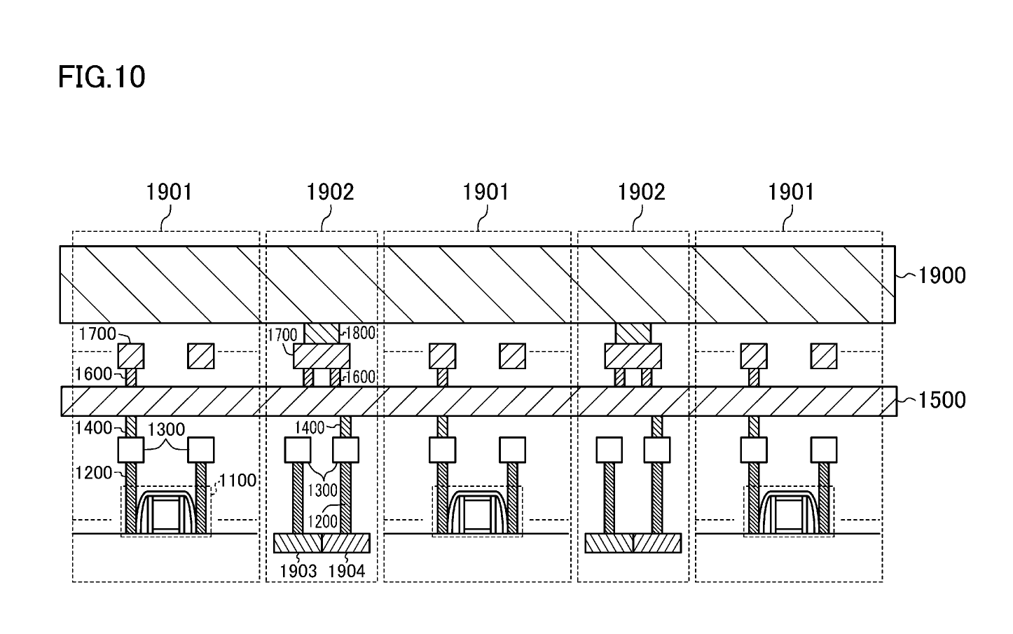

FIGS. 5 and 6 are schematic views, each of which illustrates the configuration of a semiconductor memory device according to a variation of the second embodiment. The broken line X-X of FIG. 5 indicates the cut-out portion of the cross-sectional view of FIG. 10, which will be described later.

In the first embodiment, the memory cell array 101 of the semiconductor memory device 10 is the single-block memory cell array 101. Different from the first embodiment, a semiconductor memory device 30 shown in FIGS. 5 and 6 includes a plurality of memory cell sub-arrays 511 and a plurality of power interconnect contact regions 530.

More specifically, in FIG. 5, the plurality of memory cell sub-arrays 511 are formed by dividing a memory cell array. The power interconnect contact region 530 is located between each pair of the memory cell sub-arrays 511. The power interconnect contact regions 530 are connected to the power interconnect provided at an upper layer. Each power interconnect contact region 530 includes an ESD protection circuit, which is located between the power interconnect and a ground interconnect and connected to the corresponding ones of the memory cell sub-arrays 511 and the cutting drive circuits 103, directly under the power interconnect.

In FIG. 5, the plurality of memory cell sub-arrays 511 and the plurality of power interconnect contact regions 530 including the respective ESD protection circuits are alternately arranged in the direction orthogonal to the extending direction of column selection lines BL. Alternatively, as shown in FIG. 6, the plurality of memory cell sub-arrays 511 and the plurality of power interconnect contact regions 530 including the respective ESD protection circuits may be arranged in the direction orthogonal to the extending direction of row selection lines WL. In short, the power interconnect contact region 530 may be located between at least one of pairs of the plurality of memory cell sub-arrays 511. Then, the power interconnect and the ground interconnect of the power interconnect contact region 530 can be used, thereby allowing a current to easily flow to memory cells included in the memory cell sub-arrays 511.

In FIGS. 5 and 6, a single cutting drive circuit 103 may be provided.

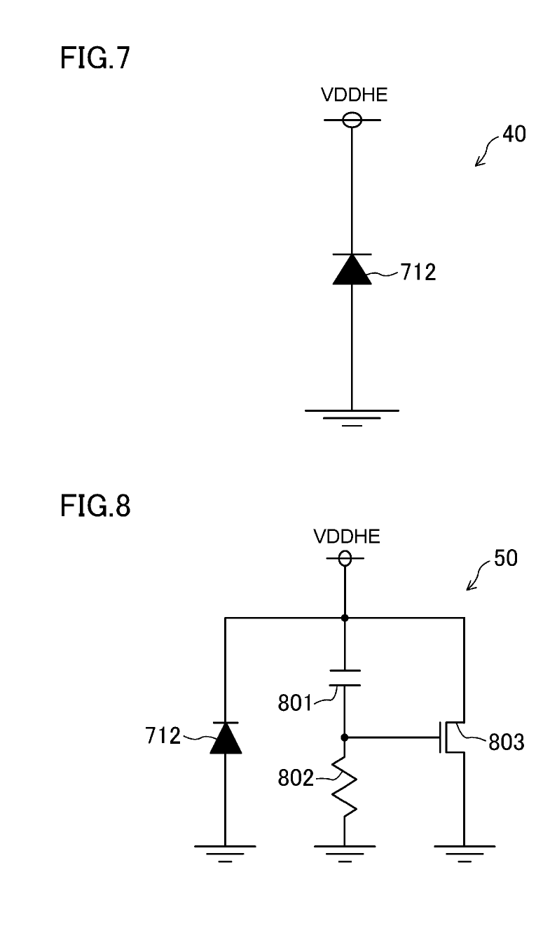

FIGS. 7 and 8 illustrate example ESD protection circuits provided in the semiconductor memory device according to the second embodiment.

An ESD protection circuit 40 of FIG. 7 includes a diode 712 made of p-type and n-type semiconductor diffusion layers. The diode 712 is connected to ground at an anode, and connected to VDDHE, which is a cutting power source of the electric fuses, at a cathode. A reverse serge voltage is discharged from the ground interconnect to the cutting power source VDDHE.

In addition to the diode 712 of FIG. 7, an ESD protection circuit 50 of FIG. 8 includes a capacitive element 801, which is a transistor, a resistive element 802 made of polysilicon used as a non-silicide gate material, etc., and an n-type MIS transistor 803 to absorb a forward surge voltage.

More specifically, the capacitive element 801 is connected to the power source VDDHE at one end, and connected to the resistive element 802 at the other end. A node connected to the capacitive element 801 and the resistive element 802 is connected to the gate of the n-type MIS transistor 803. The other end of the resistive element 802 is connected to ground. The n-type MIS transistor 803 is connected to the power source VDDHE at a drain, and connected to ground at a source.

In this ESD protection circuit 50, when the surge voltage is applied to the power source VDDHE, the potential of the power source VDDHE increases and the gate potential of the n-type MIS transistor 803 also increases. As a result, the power source VDDHE is connected to the ground to absorb the forward serge voltage. All the above-described elements of the ESD protection circuits are at lower layers of the power interconnect layer. When the power source VDDHE is turned on, the gate of the n-type MIS transistor 803 has a high potential of 0 V or higher.

As described above, in the semiconductor memory device 30 according to these variations, the plurality of memory cell sub-arrays 511 formed by dividing the memory cell array are separately arranged, and the cutting drive circuits 103 are separately arranged at the both ends of the memory cell array on the column selection line BL. This further suppresses an increase in the area and differences in the cutting quality.

Furthermore, the power interconnect contact region 530 is located between each pair of the plurality of memory cell sub-arrays 511, and the ESD protection circuit is located directly under the power interconnect contact region 530, thereby effectively exhibiting the function of the ESD protection. This sufficiently suppresses the influence of parasitic resistances at current paths which allow cutting currents of the electric fuses to flow, thereby maintaining high cutting quality.

In these variations, the ESD protection circuit is located directly under the power interconnect. With this configuration, the vacant area under the power interconnect is efficiently utilized and an increase in the circuit area is further suppressed, as compared to the case where the ESD protection circuit is located outside.

### Third Embodiment

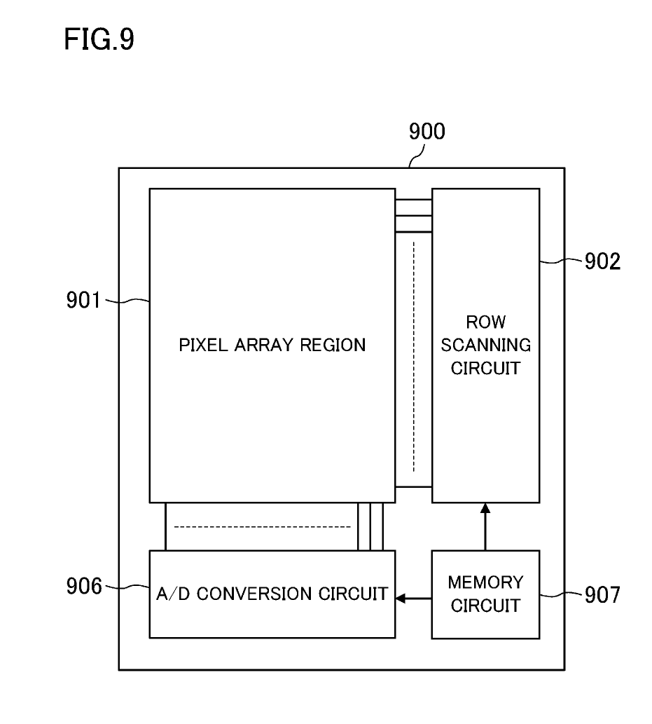

FIG. 9 is a schematic view illustrating the configuration of a semiconductor device according to a third embodiment.

A semiconductor device 900 shown in FIG. 9 is an imaging section photoelectrically converting a subject image. The semiconductor device 900 includes a pixel array region 901 of a plurality of pixels arranged in an array, and a row scanning circuit 902 performing row scanning to sequentially select rows of the pixel array region 901. Analog pixel data is output from a pixel section of the pixel array region 901, which belongs to the row selected by the row scanning circuit 902.

The semiconductor device 900 according to this embodiment includes an A/D conversion circuit 906, which receives an output signal (analog quantity) of the pixel array region 901 and converts the signal to digital. The semiconductor device 900 further includes a memory circuit 907, which supplies the output signal to the row scanning circuit 902 or the A/D conversion circuit 906 based on a control signal from the outside, and trims the analog quantity of the row scanning circuit 902 or the analog quantity used in the A/D conversion circuit 906.

The trimming of the analog quantity of the row scanning circuit 902 and the A/D conversion circuit 906 is particularly important in view of improving the image quality. In order to improve the image quality, the number of metal interconnect layers of the memory circuit 907 is low and the interconnect layers have small thicknesses. That is, the power interconnects tend to have high resistance, and the power source for the memory cells also tend to have high resistance.

The memory circuit 907 may be any of the semiconductor memory devices shown in FIGS. 1, 3, 5, and 6. This embodiment will be described where the semiconductor memory device 30 of FIG. 5 is used. Specifically, the memory circuit 907 has the same arrangement of the memory cell sub-arrays 511 including the electric fuse arrays, the cutting drive circuits 103, and the ESD protection circuit, as the semiconductor memory device shown in FIG. 5.

FIG. 10 is a cross-sectional view of the semiconductor memory device taken along the line X-X of FIG. 5. FIG. 10 schematically illustrates the cross-section from the transistor to the uppermost interconnect. In FIG. 10, the ESD protection circuit 40 of FIG. 7 is used as the ESD protection circuit of FIG. 5.

As shown in FIG. 10, memory cell sub-array regions 1901, which correspond to the reference numeral 511 of FIG. 5, and power interconnect contact (ESD protection circuit) regions 1902, which correspond to the reference numeral 530 of FIG. 5, are alternately arranged.

In each memory cell sub-array region 1901, a transistor section 1100, a contact 1200, a first metal layer 1300, a contact 1400, a second metal layer 1500, a contact 1600, and a third metal layer 1700 are sequentially stacked from the bottom. The contact 1200 connects the transistor section 1100 to the first metal layer 1300. The contact 1400 connects the first metal layer 1300 to the second metal layer 1500. The contact 1600 connects the second metal layer 1500 to the third metal layer 1700. FIG. 10 is a partial cross-sectional view of the memory cell array shown in FIG. 5, and thus does not show memory cells such as eFuse devices.

In each power interconnect contact (ESD protection circuit) region 1902, an n-type diffusion layer 1903 of an ESD protection diode, a p-type diffusion layer 1904 of the ESD protection diode, the contact 1200, the first metal layer 1300, the contact 1400, the second metal layer 1500, the contact 1600, the third metal layer 1700, a contact 1800, and an uppermost metal layer 1900 are sequentially stacked from the bottom. The contact 1200 connects the n-type diffusion layer 1903 of the ESD protection diode and the p-type diffusion layer 1904 of the ESD protection diode to the first metal layer. The contact 1400 connects the first metal layer 1300 to the second metal layer 1500. The contact 1600 connects the second metal layer 1500 to the third metal layer 1700. The contact 1800 connects the third metal layer 1700 to the uppermost metal layer 1900. In FIG. 10, the uppermost metal layer 1900 and the second metal layer 1500 are ground interconnects.

In FIG. 9, the configuration corresponding to each memory cell sub-array 511 included in the memory circuit 907 is formed by the third metal layer 1700 and the underlying layers. The power interconnects for the memory circuit 907 and the memory cell sub-arrays 511 are formed by the uppermost metal layer 1900 located higher than the third metal layer 1700.

As described above, in the semiconductor device according to this embodiment, any of the semiconductor memory devices according to the first and second embodiments may be used as the memory circuit 907. The output signal can be supplied to the row scanning circuit 902 or the AID conversion circuit 906.

This configuration suppresses the differences in cutting the electric fuses included in the memory circuit 907. Since the resistance is low after the cutting, the power consumption decreases in a reading operation of an output signal from the memory circuit 907.

In the semiconductor device according to this embodiment, the memory circuit 907 is formed by the third metal layer 1700 and the underlying layers. The power interconnect for the memory circuit 907 is formed by the uppermost metal layer 1900. This configuration supplies the power to the memory circuit 907 from the uppermost metal layer 1900 having lower power interconnect resistance than the underlying interconnects, thereby maintaining stable cutting quality of the electric fuses. Since the resistance is low after the cutting, the power consumption in a reading operation of the output signal from the memory circuit 907 decreases.

From the foregoing, the noise in the row scanning circuit 902 controlling the pixel section of the pixel array region 901, and the A/D conversion circuit 906 decreases. This also contributes to improvement in the image quality and the analog characteristics of the semiconductor device including the imaging section.

While in this embodiment, the semiconductor memory device 30 of FIG. 5 is applied to a solid imaging sensor including an imaging section, it is applicable to any target.

In the above-described embodiments, the electric fuses are used as the non-volatile devices, but may be at least once rewritable non-volatile devices. For example, the non-volatile devices may be metal interconnect fusing fuses, fuses breaking contact between metal interconnect layers, anti-fuses breaking gate sections of transistors, or transistor deteriorating fuses, which allow an excessive current to flow to the transistors and deteriorate the transistors. The non-volatile devices may be electrically erasable programmable read only memory (EEPROM) cells, each of which includes a floating gate.

As described above, the semiconductor memory device according to the present disclosure has been described based on the above-described embodiments. The configuration of the semiconductor memory device according to the present disclosure is not limited to the above-described embodiments. It may be modified or changed within the scope of the present disclosure. For example, the present disclosure includes replacement of part of the constituent elements with alternatives not shown in the embodiments.

The present disclosure is useful for semiconductor devices manufactured in advanced miniaturized processes, and the circuit technology of semiconductor devices including few interconnect layers and having high interconnect resistance. The present disclosure is applicable to wide range of electronics using such semiconductor devices.

What is claimed is:

1. A semiconductor memory device including a non-volatile device array of once rewritable non-volatile devices arranged in a matrix; the device comprising:
a plurality of non-volatile device sub-arrays formed by dividing the non-volatile device array;
a power interconnect contact region provided between at least one of pairs of the plurality of non-volatile device sub-arrays, and connected to a power interconnect provided at an upper layer of the non-volatile device array; and
an ESD protection circuit located in the power interconnect contact region between ground and a power source for the non-volatile devices.

2. The semiconductor memory device of claim 1, wherein
the ESD protection circuit includes a diode connected to the power source at a cathode and connected to the ground at an anode.

3. The semiconductor memory device of claim 2, wherein
the ESD protection circuit includes an n-type MIS transistor connected to the power source at a drain and connected to the ground at a source, and
a gate of the n-type MIS transistor has a potential of 0 V or more when the power source is turned on.

4. The semiconductor memory device of claim 3, wherein the ESD protection circuit includes
a resistive element connected to the gate of the n-type MIS transistor at one end and connected to the ground at another end, and
a capacitive element connected to the gate of the n-type MIS transistor at one end and connected to the power source at another end.

5. A semiconductor memory device including a non-volatile device array of once rewritable non-volatile devices arranged in a matrix, the device comprising:
one or more column selection lines corresponding to columns of the non-volatile device array; and
a plurality of write driver circuits separately provided on the column selection line such that the plurality of write driver circuits sandwich at least one of the non-volatile devices.

6. The semiconductor memory device of claim 5, wherein
the plurality of write driver circuits are provided at both ends of the column selection line to sandwich the non-volatile device array.

7. The semiconductor memory device of claim 5, further comprising:
a plurality of non-volatile device sub-arrays formed by dividing the non-volatile device array, and
the plurality of write driver circuits sandwich at least one of the non-volatile device sub-arrays.

8. The semiconductor memory device of claim 5, wherein
each of the write driver circuits is a p-type MIS transistor connected to a power source for the non-volatile devices at a source and connected to the column selection line at a drain.

9. The semiconductor memory device of claim 8, wherein
a gate potential of the p-type MIS transistor is generated by a peripheral circuit located in the non-volatile device array and supplied via an interconnect at an upper layer of the non-volatile device array.

10. A semiconductor device comprising:
the semiconductor memory device of claim 1;
an imaging section including a plurality of pixels arranged in a matrix;
a row scanner sequentially performing row scanning of the plurality of pixels corresponding to rows of the imaging section; and
an analog digital converter simultaneously converting analog pixel signals output from ones of the plurality of pixels subjected to the row scanning to digital pixel data, wherein
an output signal of the semiconductor memory device is supplied to the row scanner or the analog digital converter.

11. A semiconductor device comprising:
the semiconductor memory device of claim 5;
an imaging section including a plurality of pixels arranged in a matrix;
a row scanner sequentially performing row scanning of the plurality of pixels corresponding to rows of the imaging section; and
an analog digital converter simultaneously converting analog pixel signals output from ones of the plurality of pixels subjected to the row scanning to digital pixel data, wherein
an output signal of the semiconductor memory device is supplied to the row scanner or the analog digital converter.

12. The semiconductor device of claim 10, wherein
the power interconnect for the semiconductor memory device is an uppermost interconnect of the semiconductor device.
